(19) United States
(12) Patent Application Publication
(10) Pub. No.: US 2004/0070462 A1
(43) Pub. Date: Apr. 15, 2004

(54) Oscillator package

(76) Inventors: Iyad Alhayek, Schaumburg, IL (US); Jaroslaw Adamski, Streamwood, IL (US); Marc Black, South Bend, IN (US); Craig Ernsberger, Granger, IN (US); Jason B. Langhorn, South Bend, IN (US)

Correspondence Address: Mark P. Bourgeois, CTS Corporation, 905 West Boulevard North, Elkhart, IN, 46514, US

(21) Appl. No.: 10/268,867

(22) Filed: Oct. 10, 2002

(51) Int. Cl. H03B 5/32

(52) U.S. Cl. 331/158

(57) ABSTRACT

An oscillator package with an improved crystal mount. The oscillator package has substrate with a top cavity and a bottom cavity. Vias extend through the substrate between the top and bottom cavities. A semiconductor die is located in the bottom cavity and is covered by a sealant. A crystal is located in the top cavity. The crystal is mounted in the top cavity using a thermosonically deposited gold bump. The gold bump is attached between an electrode pad and a contact pad. The gold bump provides an electrical connection between the crystal and the substrate and supports the crystal. A cover and seal ring are attached to substrate to hermetically seal the top cavity.

### TECHNICAL FIELD

This invention relates to crystal oscillators for radio-frequency devices, and in particular, to a package for crystal oscillators and a method of manufacturing an oscillator package.

### BACKGROUND

Oscillators use a piezoelectric material such as a quartz crystal and temperature compensation circuitry to provide a reliable and stable oscillator output signal. The crystal and circuitry are mounted in an electronic package. These devices are commonly found in portable radio frequency (RF) communication equipment, such as cellular telephones, pagers and wireless modems. As consumer demand continually drives down the size of cellular telephones and other communications equipment, there is a need for oscillators that have smaller dimensions and reduced weight.

The height, width and depth of the oscillator are dependent upon the size of the crystal, the temperature compensation circuitry and the package dimensions. Typical prior art oscillators have dimensions of 5 mm×7 mm and 3.2 mm×5 mm. While these dimensions may appear to be small, the demand for smaller cellular telephones and other electronic products requires even smaller physical dimensions.

U.S. Pat. Nos. 6,229,249, 6,229,404 and 5,438,219 show a crystal oscillator that has the crystal attached to the substrate by the use of a conductive adhesive. The conductive adhesive is located between a conductive pad on the crystal and a conductive pad on a substrate. The contact between a crystal and a substrate must provide good electrical contact while at the same time isolating the crystal from mechanical shock and allowing for mismatches in thermal expansion. Unfortunately, conductive adhesives tend to outgas overtime and leave deposits that build up on the crystal causing a shift in the frequency of the crystal. This phenomena is known as aging.

As crystal and package sizes become smaller conductive adhesives become more difficult to use. The conductive adhesive is difficult to dispense and to control the flow of in small areas. These problems cause shorting of electrodes and crystals that are mounted to close to the adjoining substrate.

Mismatches in thermal expansion between the crystal and the package can causes mechanical stresses in the crystal during operation. These mechanical stresses cause the inflection temperature of the Bechmann curve of the crystal to shift which in turn cause a shift in the frequency of the crystal. The connection system between the crystal and package should minimize any changes in mechanical stresses imparted to the crystal over the life of the oscillator.

Therefore, a current unmet need exists for an oscillator package that has a small size that can be easily mass produced at low cost and that maintains a stable frequency of operation over the life of the oscillator.

### SUMMARY

This invention overcomes problems of the prior art by providing an oscillator package that has an improved crystal mount.

An embodiment of this invention is an oscillator that has a substrate. The substrate has a top surface, a bottom surface, and side surfaces. A first cavity is located on the bottom surface. The first cavity has a first surface and first side walls. Top contact pads are located on the top surface. Bottom contact pads are located on the first surface. Several circuit lines are located in the substrate. Several vias are located in the substrate. The vias are electrically connected to the first and second contact pads and the circuit lines. A semiconductor die is located in the first cavity and are electrically connected with the second contact pad. A sealant is located in the first cavity surrounding the semiconductor die. A seal ring pad is located on the top surface. A seal ring is attached to the seal ring pad. The seal ring defines a second cavity. A crystal is located in the second cavity. The crystal has an electrode pad. A thermosonically deposited metal bump is attached between the electrode pad and the first contact pad. The metal bump provides an electrical connection between the crystal and the substrate. The metal bump further mechanically supports the crystal. Several termination pads are located on the bottom surface and are electrically connected to the vias. A cover is attached to the seal ring to hermetically seal the second cavity.

Another embodiment of this invention is a crystal receptacle having a first base and first side walls. The first side walls define the crystal receptacle. The crystal receptacle has a receptacle area. The receptacle area takes up the majority of the overall package area. An integrated circuit receptacle has a second base and second side walls. The second side walls define the integrated circuit receptacle. A planar crystal blank has a crystal area. The crystal blank is mounted in the crystal receptacle. The crystal area takes up the majority of the receptacle area. A metal bump is located between the base and the crystal. The metal bump affixes the crystal to the base. An integrated circuit is mounted in the integrated circuit receptacle. Another metal bump is located between the second base and the integrated circuit. The other metal bump affixes the integrated circuit to the base. The integrated circuit receptacle has an integrated circuit receptacle area. The integrated circuit has an integrated circuit area. The integrated circuit area takes up the majority of the integrated circuit receptacle area.

There are other advantages and features of this invention which will be more readily apparent from the following detailed description of the preferred embodiment of the invention, the drawings, and the appended claims.

### BRIEF DESCRIPTION OF THE FIGURES

FIG. 1 is a side cross-sectional view of an oscillator package according to the present invention;

FIG. 2 is a bottom isometric view of the substrate in FIG. 1;

FIG. 3 is a top isometric view of the substrate in FIG. 1;

FIG. 4 is a top view of FIG. 3;

FIG. 5 is a top view of FIG. 2;

FIG. 6 is an enlarged side cross-sectional view showing details of the metal bump;

FIG. 7 is side cross-sectional view during the assembly process showing placing the metal bump on the crystal side;

FIG. 8 is side cross-sectional view during the assembly process showing placing the crystal;

FIG. 9 is side cross-sectional view during the assembly process showing the crystal after placement;

FIG. 10 is side view during the assembly process showing placing the metal bump on the semi-conductor die;

FIG. 11 is side cross-sectional view during the assembly process showing placing the semi-conductor die;

FIG. 12 is side cross-sectional view during the assembly process showing the die after placement;

FIG. 13 is side cross-sectional view during the assembly process showing dispensing of the sealant over the semi-conductor die;

FIG. 14 is a flow chart of the preferred assembly process sequence;

FIG. 15 is a flow chart of an alternative assembly process sequence.

### DETAILED DESCRIPTION OF PREFERRED EMBODIMENTS

While this invention is susceptible to embodiment in many different forms, this specification and the accompanying drawings disclose only preferred forms as examples of the invention. The invention is not intended to be limited to the embodiments so described, however. The scope of the invention is identified in the appended claims.

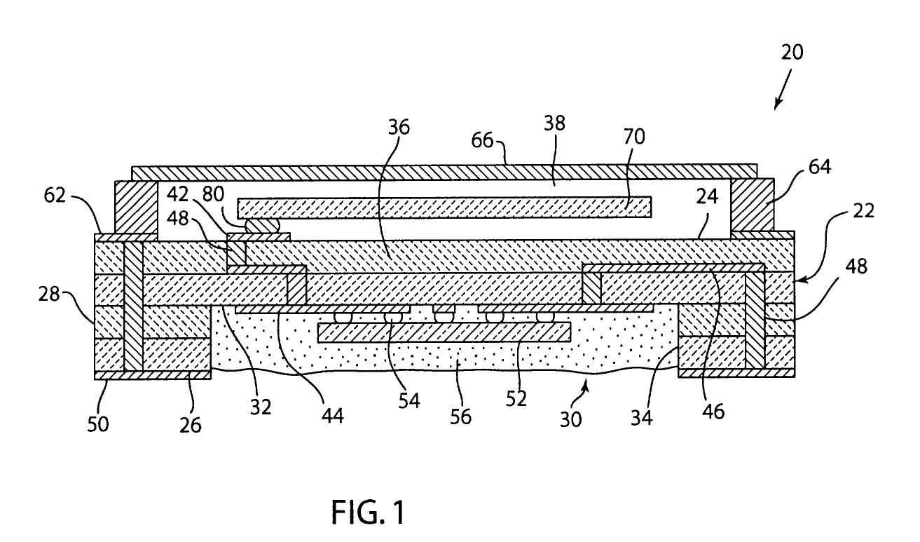

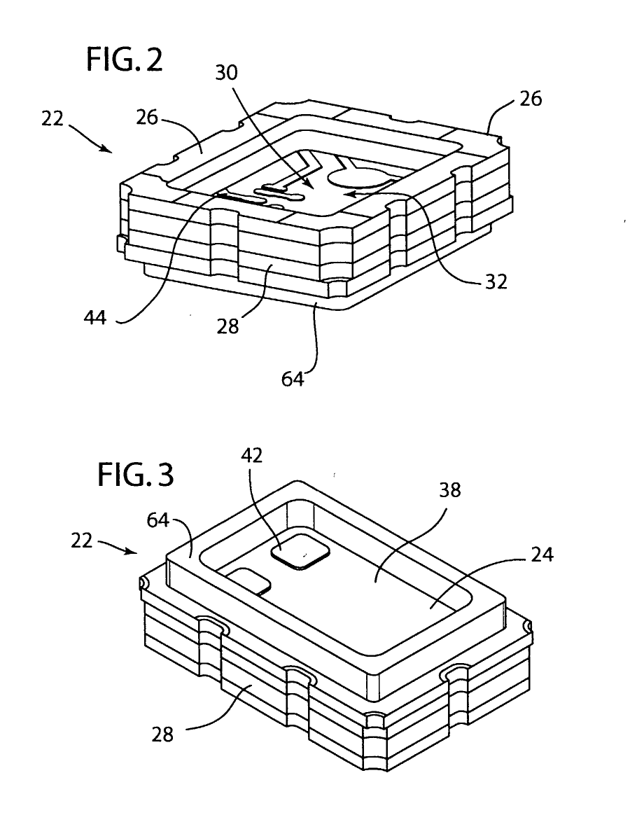

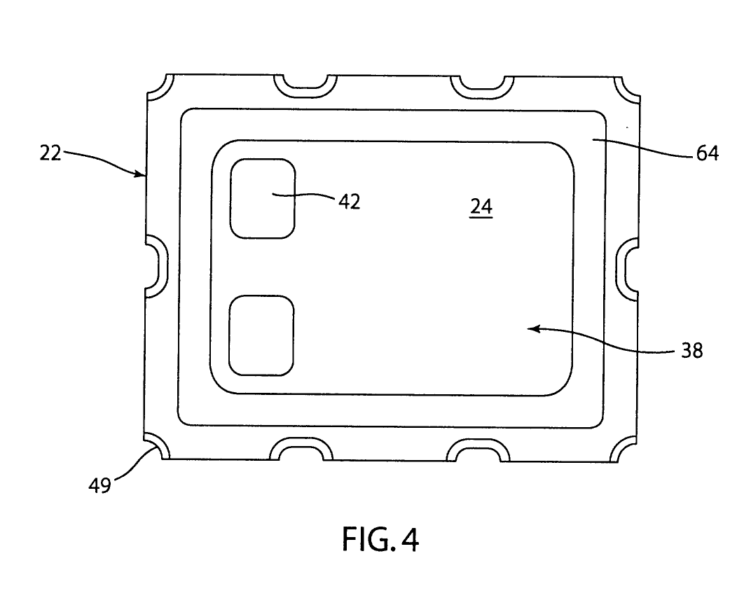

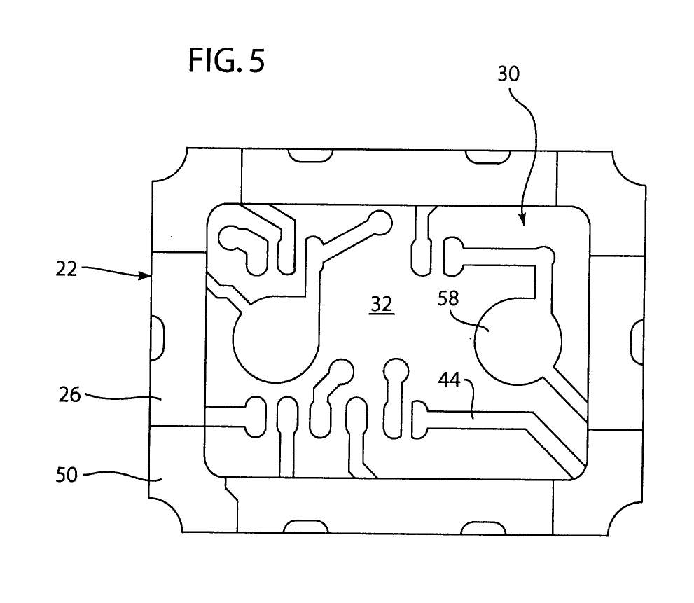

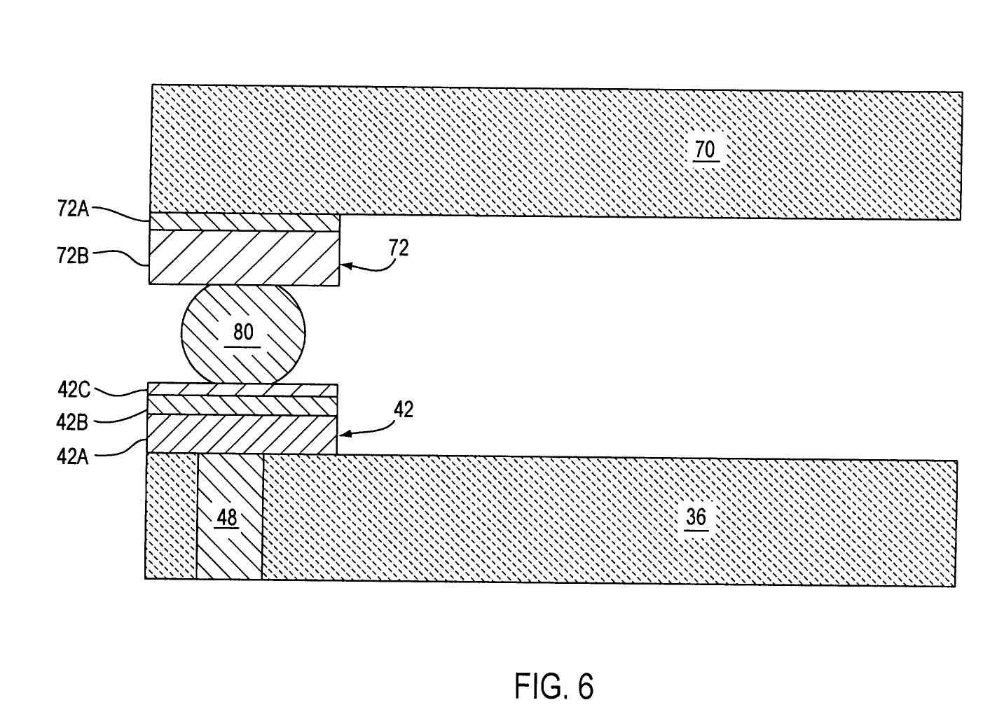

Referring to FIGS. 1-6, an oscillator package 20 includes a ceramic substrate 22. Substrate 22 is preferably a high temperature alumina ceramic. Substrate 22 has a top surface 24, a bottom surface 26, four side surfaces 28, a bottom cavity or integrated circuit receptacle 30 and a top cavity or crystal receptacle 38. The dimensions of substrate 22 preferably are less than 7.0 mm long, less than 5.0 mm in width and less than 2.0 mm in height. A bottom cavity or integrated circuit receptacle 30 is located adjacent bottom surface 26. Cavity 30 has a cavity bottom surface 32 and cavity side walls 34. A center wall 36 separates cavities 30 and 38. A top contact pad 42 is located on the top surface 24. A bottom contact pad 44 is located on the bottom cavity surface 32. Circuit lines 46 are located in substrate 22. Vias 48 are located in substrate 22. Vias 48 are electrically connected to contact pads 44 and 42. Vias 48 extend through center wall 36 and are connected with circuit lines 46.

Top contact pad 42 is composed of three layers. Layer 42A is a layer of tungsten and has a typical thickness of 0.6 mils. Layer 42B is a layer of nickel and has a typical thickness of 0.3 mils. Layer 42C is a layer of gold and has a typical thickness of 0.05 mils.

An integrated circuit or semiconductor die 52 is located in the cavity 30 and is electrically connected to contact pads 44 through a metal bump 54. Metal bump 54 is preferably a thermosonically deposited gold bump. Semiconductor die 52 is a conventional oscillator integrated circuit and preferably includes temperature compensation circuitry. A sealant 56 is located in the cavity 30 covering and surrounding the semiconductor die 52.

A seal ring pad 62 is located on top surface 24. Seal ring pad 62 is formed from gold and nickel plated tungsten. A metal seal ring 64 is attached to seal ring pad 62. Seal ring 64 is formed from Kovar and is brazed to seal ring pad 62. The seal ring 64 defines top cavity 38.

A quartz crystal 70 is located in cavity 38. The crystal has a pair of electrode pads 72. Electrode pad 72 is composed of two layers. Layer 72A is a layer of chrome and has a typical thickness of 20 angstroms. Layer 72B is a layer of gold and has a typical thickness of 2000 angstroms. One of the electrode pads wraps around the side of the crystal to connect with an electrode on the top side of the crystal. The crystal has an electrode on the top side and the bottom side.

A thermosonically deposited metal bump 80 is attached between the electrode pad 72 and top contact pad 42. The metal bump provides an electrical connection between the crystal and the substrate. The metal bump further mechanically supports the crystal without imparting excessive stress to the crystal. Metal bump 80 can be gold or an alloy of gold and palladium.

Termination pads 50 are located on bottom surface 26 and are electrically connected to vias 48. The termination pads would be soldered to an external circuit board (not shown) in order to connect with another electrical circuit such as in a cell phone, PDA or computer. A metal cover 66 is attached to the seal ring 64 to hermetically seal cavity 38. The cover is formed from Kovar and is seam welded to ring 64.

The construction of ceramic substrate 22 is described in U.S. Pat. No. 6,229,249 to Hantanaka et al. The disclosure of which is hereby incorporated by reference.

Oscillator package 20 has an overall package area that it takes up. The overall package area is defined as product of the overall length and width of package 20. The crystal receptacle 38 has a receptacle area that it takes up. The receptacle area is defined as the area surrounded by seal ring 64. The receptacle area takes up the majority of the overall package area. The integrated circuit receptacle 32 has an integrated circuit receptacle area. The integrated circuit receptacle area is defined as the area on bottom surface 32 within walls 34. The crystal blank 70 has an associated crystal area based on the length and the width of the crystal. The crystal blank 70 is mounted in the crystal receptacle 38. The crystal area takes up the majority of the receptacle area. The integrated circuit has an integrated circuit area. The integrated circuit area takes up the majority of the integrated circuit receptacle area. Since, the area taken up by the oscillator package is slightly larger than the area taken up by the crystal and the integrated circuit is mounted below the crystal, a crystal package is obtained that takes up a small amount of circuit board space and has high density.

Three oscillator packages 20 in different sizes were fabricated and tested. The packages had the following dimensions and areas:

| Package | Overall Package Size | Package Area |
|---|---|---|
| A. | 3.2 × 2.5 mm | 8 sq. mm |
| B. | 3.2 × 5.0 mm | 16 sq. mm |
| C. | 5.0 × 7.0 mm | 35 sq. mm |

| Package | Crystal Receptacle Size | Receptacle Area |
|---|---|---|
| A. | 2.36 × 1.09 mm | 2.57 sq. mm |
| B. | 4.09 × 2.31 mm | 9.45 sq. mm |
| C. | 48 × 3.61 mm | 19.78 sq. mm |

| Package | Crystal Blank Size | Blank Area |
|---|---|---|
| A. | 1.73 × 1.09 mm | 1.88 sq. mm |
| B. | 3.50 × 1.91 mm | 6.68 sq. mm |
| C. | 4.98 × 3.0 mm | 14.94 sq. mm |

For package C, the 5×7 mm package, the crystal takes up 75.5 percent of the crystal receptacle area. The crystal receptacle takes up 56.5 percent of the overall package area.

### Assembly Process

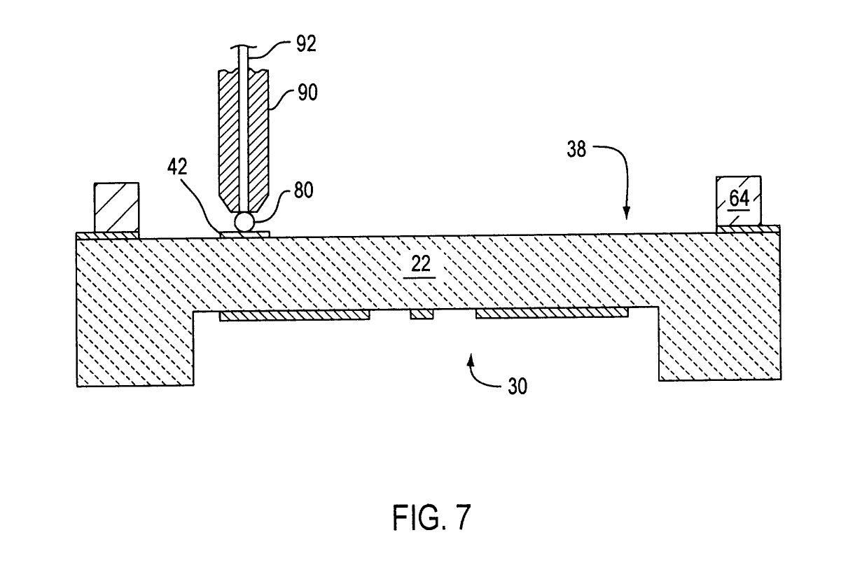

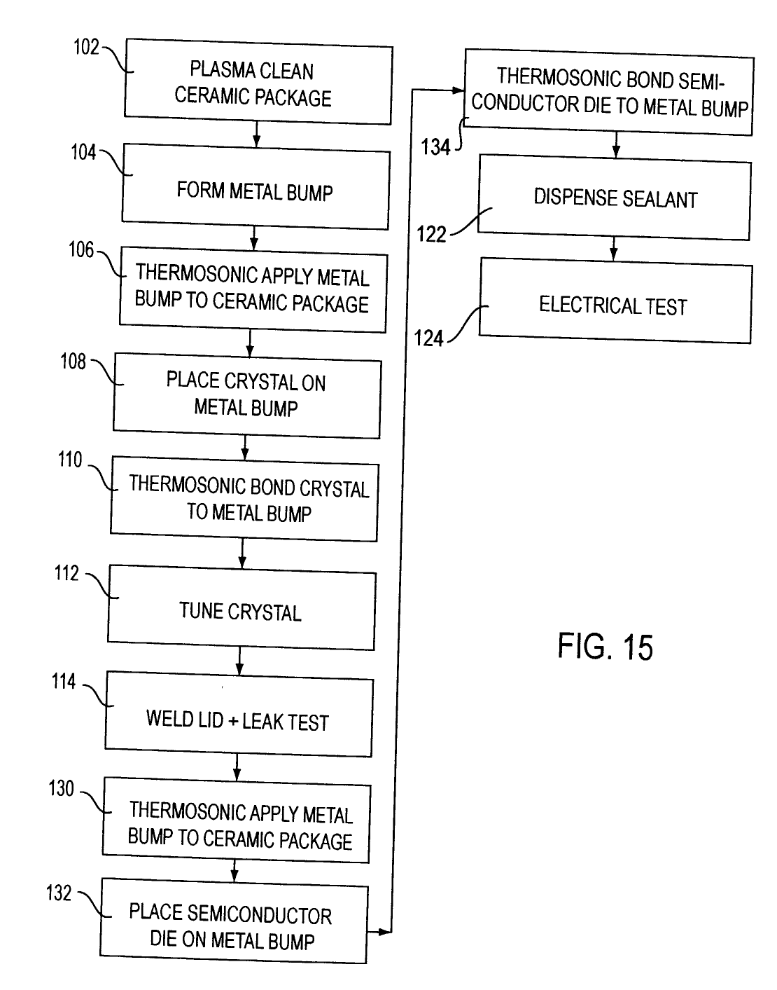

Referring to FIGS. 7-13 and 14, a process sequence for the assembly of oscillator package 20 is shown. Substrate 22 is first cleaned in a conventional plasma reactor at step 102 in FIG. 15 to remove any surface contaminants that might be present. The plasma used is a mixture of argon and oxygen. In FIG. 7, a hollow capillary 90 contains a wire 92. Wire 92 is gold or an alloy of gold and palladium. Capillary 90 is commercially available from Small Precision Tools Corporation as model number UTZ120-46DI-C-1/16-16 mm. Capillary 90 is used with a F&K Delvotek model 6200 thermosonic wire bonder. Substrate 22 is placed in a fixture (not shown) that is mounted to a heated stage (not shown) that is part of the wire bonder. The fixture would contain multiple substrates 22. The wire is a 1.5 mil diameter gold palladium alloy wire from Tanaka corporation model GBC (99% Au 1% Pd). The wire bonding tool first forms a ball in the air at step 104 called a free air ball by melting the end of the wire using an electric current. The diameter of the free air ball is 3 times the wire diameter in this case 4.5 mils. The formed air ball is then placed onto contact pad 42 at step 106. A bondforce pressure is applied downward on ball by capillary 90. The bondforce pressure is 45 grams. The stage is heated to 150 degrees centigrade and the capillary thermosonically vibrated. The thermosonic capillary operates for 35 milliseconds at a power level of 0.4 watts and a frequency of 63.5 kHz. The thermosonic power is turned off and the capillary removed leaving metal bump 80 attached to contact pad 42 by a gold-gold interface. The resulting metal bump 80 has an average overall height of 120 microns and a diameter of 120 microns. The capillary is then moved to the next contact pad 42 to repeat depositing another metal bump 80. The process can be repeated as many times as desired until the required number of metal bumps are deposited.

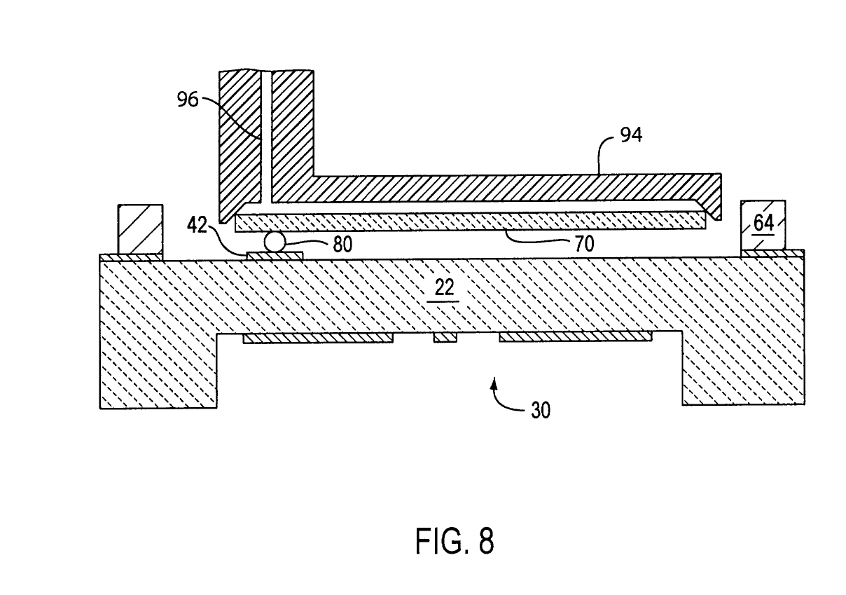

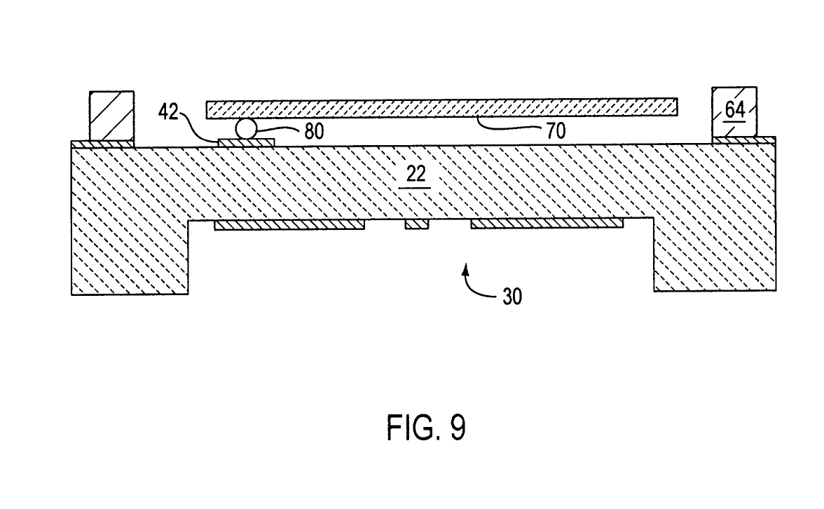

Next, at step 108 and in FIG. 8, crystal 70 is picked up by a collect tool 94 using a vacuum applied through port 96. The tool 94 and crystal 70 are placed over contact pads 42 such that metal bumps 80 are in contact with electrode pads 72. Tool 94 is available from Small Precision Tools Corporation. Tool 94 is attached to a Semiconductor Equipment Corp. model 410 thermosonic flip chip attach machine. The fixture holding substrate 22 would be mounted in the machine on top of a heated stage. Tool 94 is thermosonically vibrated at step 110 to attach metal bumps 80 to pads 42. A bondforce pressure is applied downward by tool 94. The bondforce pressure is 75 grams per bump. The stage is heated to 250 degrees centigrade and tool 94 is thermosonically vibrated. The tool is thermosonically vibrated for 6 milliseconds at a power level of 1.6 watts and a frequency of 62.5 kHz. The thermosonic power is turned off and tool 94 is left in contact for 1 second. Tool 94 is then removed leaving metal bump 80 attached to contact pad 72 by a gold-gold interface. As seen in FIG. 9, crystal 70 is now attached to substrate 22.

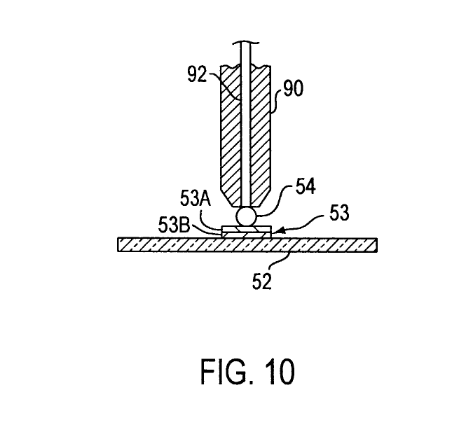

Next, at step 112, the fixture containing substrate 22 is placed in a vacuum chamber and contact probes (not shown) are brought into contact with tuning pads 58. A mask is placed over the top of the crystal such that only the gold plated electrode area on top is showing through the mask. An oscillating signal is applied to the tuning pads which in turn are connected to crystal 70 causing the crystal to vibrate at a resonant frequency. The resonant frequency of crystal 70 is then adjusted to the desired frequency by removing some of the gold covering the electrode using an ion beam. When the desired frequency is reached, the substrate is removed from the vacuum chamber. Next, at step 114, the substrate 22 is placed into a chamber containing dry nitrogen where cover 66 is placed over seal ring 64 and seam welded using conventional welding equipment. The crystal is then leak checked by filling the chamber with helium and then drawing a vacuum on the chamber while a sensor detects any helium that may be leaking from inside the sealed crystal. Crystal 70 is now tuned and hermetically sealed as shown in FIG. 10.

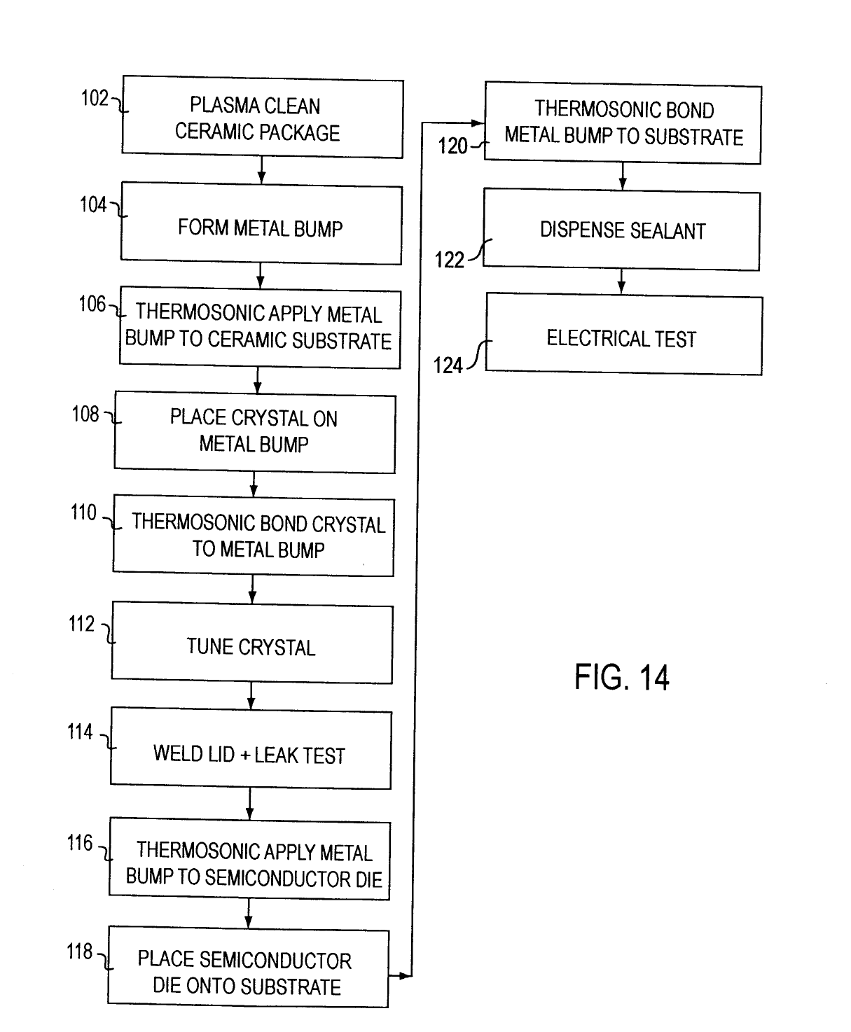

Next, as shown in FIG. 10, the semiconductor die 52 is placed into the wire bonding machine. The process of depositing a metal bump is repeated as in FIG. 7 to deposit metal bump 54 onto a die contact pad 53. Die contact pad 53 is made up of an aluminum layer 53A and a nickel layer 54B. Nickel layer 54B is attached to the silicon die and provides better adhesion for the aluminum. The deposition of metal bump 54 step is shown at step 116 in FIG. 14. It is preferred to deposit metal bump 54 to contact pads 53 first because contact pads 44 are larger than pad 53.

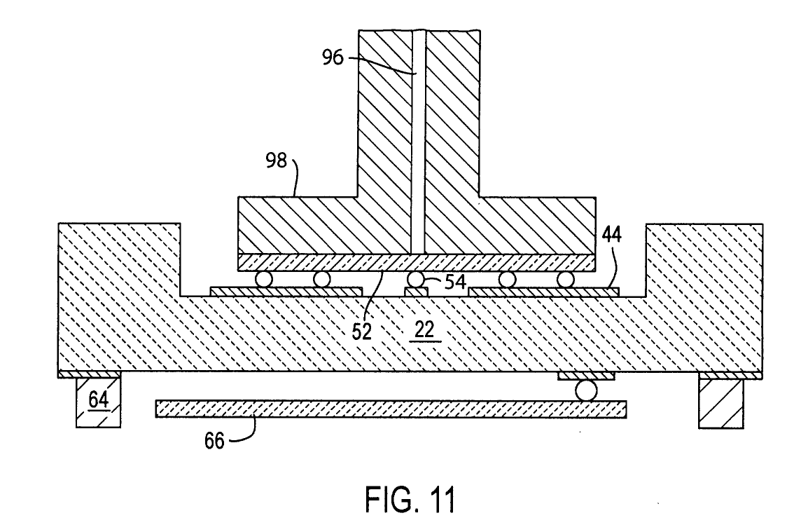

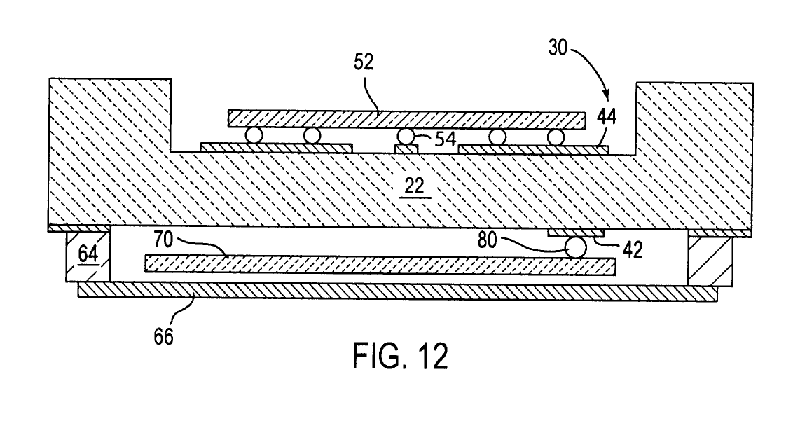

Next, in FIG. 11, semi-conductor die 52 is picked up by a flat tool 98 using a vacuum applied through port 96. The tool 98 and die 52 are placed over contact pads 44 at step 118 such that metal bumps 54 are in contact with input output pads on die 54 (not shown). Tool 98 is available from Small Precision Tools Corporation. Tool 98 is attached to a Semiconductor Equipment Corp. model 410 thermosonic flip chip attach machine. The fixture holding substrate 22 would be mounted in the machine on top of a heated stage. Tool 98 is thermosonically vibrated at step 120 to attach metal bumps 54 to the die pads. A bondforce pressure is applied downward by tool 98. The bondforce pressure is 35 grams per bump. The stage is heated to 200 degrees centigrade and tool 98 is thermosonically vibrated. The tool is thermosonically vibrated for 0.4 seconds at a power level of 1.5 watts and a frequency of 62.5 kHz. The thermosonic power is turned off and tool 98 is removed leaving metal bump 54 attached to contact pad 44 by a gold-gold interface. As seen in FIG. 12, die 52 is now attached to substrate 22.

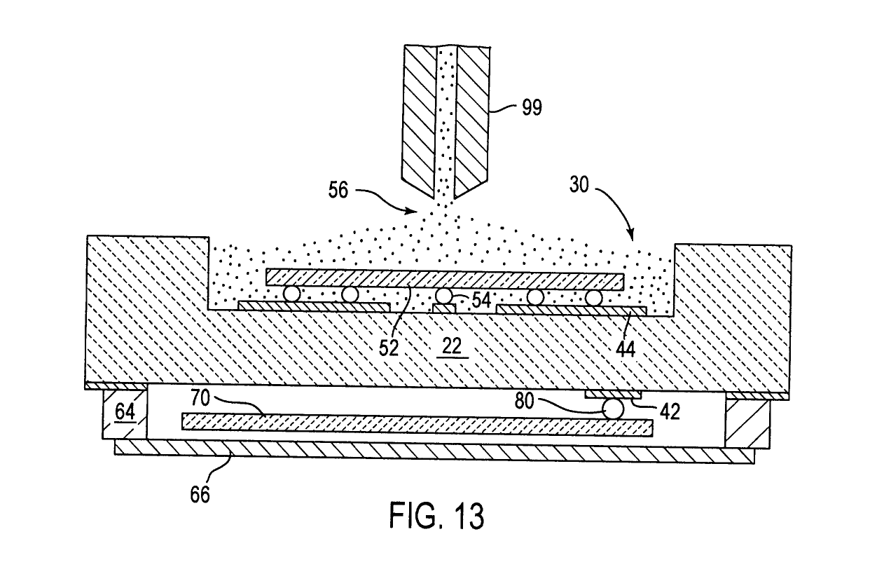

Next, in FIG. 13 and at step 122, a sealant 56 is dispensed through a tube 99 into cavity 30 covering die 52. Sealant 56 can be a silicone sealant such as RTV silicone from Dow Corning Corporation. Sealant 56 protects die 52 and its electrical connects from corrosion and mechanical contact. The oscillator package is then electrically tested at step 124.

### Remarks

The metal bump 80 was shown as being deposited on to substrate 22 and then the crystal 70 attached to metal bump 80. Alternatively, the metal bump could be placed onto the crystal first and then the bump attached to the substrate. Turning now to FIG. 15 a flow chart of an alternative assembly process sequence is shown. FIG. 15 is similar to FIG. 14 except that steps 130, 132 and 132 have replaced steps 116, 118 and 120. At step 130, the metal bump 54 is applied to contact pad 44. At step 132, the semiconductor die 52 is placed on top of bump 54 using tool 98. At step 134, the die 52 is thermosonically bonded to metal bump 54 using tool 98.

The present invention has many advantages. In an oscillator package, the crystal tends to have a higher defect rate. By attaching the crystal first and then tuning the crystal, any defective parts can be discovered prior to the attachment of the more expensive semiconductor die. Therefore, any resulting defective parts contain the substrate and die only and does not include the semiconductor die. This results in a cost savings over other assembly methods.

Using a metal bump to attach the crystal to the substrate allows for the fabrication of denser packages and stabilizes the mechanical stresses imparted to the crystal over the life of the oscillator. The metal bump minimizes any changes in stress between the package and the crystal over time. The metal bump allows for better control of dimensional placement of the crystal within the substrate and eliminates the problem of conductive adhesive flowing to undesired locations causing shorts. The metal bump further eliminates crystal aging problems due to outgassing of the conductive adhesive.

Numerous variations and modifications of the embodiments described above may be effected without departing from the spirit and scope of the novel features of the invention. It is to be understood that no limitations with respect to the specific system illustrated herein are intended or should be inferred. It is, of course, intended to cover by the appended claims all such modifications as fall within the scope of the claims.

We claim:

1. An oscillator comprising:
a) an insulative substrate having a top surface, a bottom surface, and side surfaces;
b) a first cavity located on the bottom surface, the first cavity having a first surface and first side walls;
c) at least one first contact pad located on the top surface;
d) at least one second contact pad located on the first surface;
e) a plurality of circuit lines located in the substrate;
f) a plurality of vias located in the substrate, the vias electrically connected to the first and second contact pads and the circuit lines;
g) a semiconductor die located in the first cavity and electrically connected with the second contact pad;
h) a sealant located in the first cavity surrounding the semiconductor die;
i) a seal ring pad located on the top surface;
j) a seal ring attached to the seal ring pad, the seal ring defining a second cavity;
k) a crystal located in the second cavity, the crystal having an electrode pad;
l) a thermosonically deposited metal bump attached between the electrode pad and the first contact pad, the metal bump providing an electrical connection between the crystal and the substrate, the metal bump further mechanically supporting the crystal;
m) a plurality of termination pads located on the bottom surface and electrically connected to the vias; and
n) a cover attached to the seal ring for hermetically sealing the second cavity.

2. The oscillator according to claim 1 wherein the first contact pad further comprises:
a) a tungsten layer attached to the substrate;
b) a nickel layer overlaying the tungsten layer; and
c) a gold layer overlaying the nickel layer, the metal bump attached to the gold layer.

3. The oscillator according to claim 1 wherein the electrode pad further comprises:
a) a chrome layer attached to the crystal; and
b) a gold layer overlaying the chrome layer, the metal bump attached to the gold layer.

4. The oscillator according to claim 1 wherein the substrate has a length less than 5.0 mm, a width less than 3.2 mm and a height less than 2.0 mm.

5. The oscillator according to claim 1 wherein the semiconductor die is attached to the second contact pad by an thermosonically deposited metal bump.

6. The oscillator according to claim 1 wherein the metal bump is gold.

7. The oscillator according to claim 1 wherein the metal bump is an alloy of gold and palladium.

8. The oscillator according to claim 1 wherein the substrate is a multi-layered ceramic.

9. The oscillator according to claim 8 wherein the vias, circuit lines, contact pads and seal ring pad are tungsten.

10. An oscillator comprising:
a) a substrate having a top surface and a bottom surface and four walls extending outwardly from the bottom surface, the four walls defining a bottom cavity therein;
b) a seal ring attached to the top surface, the seal ring defining a top cavity;
c) a plurality of first contact pads located on the top surface;
d) a plurality of second contact pads located on the bottom surface;
e) a plurality of circuit lines located in the substrate;
f) a plurality of vias located in the substrate, the vias extending through the substrate and electrically connected to the first and second contact pads and the circuit lines;
g) a semiconductor die located in the bottom cavity and electrically connected with the second contact pads;
h) a sealant covering the semiconductor die;
i) a crystal located in the top cavity, the crystal having an electrode pad;
j) a thermosonically deposited metal bump attached between the electrode pad and the first contact pad, the metal bump providing an electrical connection between the crystal and the substrate, the metal bump mechanically supporting the crystal; and
k) a cover attached to the seal ring for hermetically sealing the top cavity.

11. The oscillator according to claim 10 wherein the first contact pad further comprises:
a) a tungsten layer attached to the substrate;
b) a nickel layer overlaying the tungsten layer; and
c) a gold layer overlaying the nickel layer, the metal bump attached to the gold layer.

12. The oscillator according to claim 10 wherein the electrode pad further comprises:
a) a chrome layer attached to the crystal; and
b) a gold layer overlaying the chrome layer, the metal bump attached to the gold layer.

13. The oscillator according to claim 10 wherein the substrate has a length less than 5.0 mm, a width less than 3.2 mm and a height less than 2.0 mm.

14. A method of manufacturing an oscillator package comprising:
a) providing a substrate having a top surface, a bottom surface and four walls extending outwardly from the bottom surface, the four walls defining a bottom cavity therein, the top surface having a plurality of first contact pads, the bottom surface having a plurality of second contact pads, vias extending through the substrate and connected to the first and second contact pads, a seal ring attached to the top surface, the seal ring defining a top cavity;
b) depositing a metal bump on the first contact pad;
c) placing a crystal electrode attached to a first surface of a crystal over the metal bump;
d) contacting a thermosonic transducer to a second surface of the crystal;
e) applying thermosonic energy to the crystal such that the metal bump attaches to the crystal electrode;
f) removing the thermosonic transducer;
g) tuning the crystal to a resonant frequency; and
h) welding a cover onto the seal ring such that the crystal is hermetically sealed.

15. The method of manufacturing an oscillator package according to claim 14, further comprising:
a) depositing a metal bump on the second contact pad;
b) placing a semiconductor die having a die electrode attached to a first surface of the die over the metal bump;
c) contacting a thermosonic transducer to a second surface of the die;
d) applying thermosonic energy to the die such that the metal bump attaches to the die electrode;
e) removing the thermosonic transducer; and
f) dispensing a sealant into the bottom cavity over the die.

16. The method of manufacturing an oscillator package according to claim 14, further comprising:
a) depositing a metal bump on onto a first surface of a semiconductor die;
b) placing the metal bump in adjacent contact with the second contact pads;
c) contacting a thermosonic transducer to a second surface of the die;
d) applying thermosonic energy to the die such that the metal bump attaches to the second contact;
e) removing the thermosonic transducer; and
f) dispensing a sealant into the bottom cavity over the die.

17. The method of manufacturing an oscillator package according to claim 14, wherein the tuning step further comprises:
a) placing the oscillator package in a vacuum;
b) contacting a tuning pad with a test probe;
c) measuring the resonant frequency of the crystal;
d) depositing a layer of gold onto a central portion of the crystal, the layer of gold being deposited until the desired resonant frequency is obtained;
e) removing the test probe; and
f) removing the oscillator package from the vacuum.

18. The method of manufacturing an oscillator package according to claim 14, further comprising:
a) cleaning the top surface prior to depositing the metal bump on the first contact pad.

19. The method of manufacturing an oscillator package according to claim 18, wherein the cleaning is performed in a plasma reactor.

20. The method of manufacturing an oscillator package according to claim 14, wherein the substrate has a length less than 5.0 mm, a width less than 3.2 mm and a height less than 2.0 mm.

21. An oscillator package comprising:
a) a substrate having a center wall, the center wall located between a top cavity and a bottom cavity, the center wall having a first surface adjacent the top cavity and a second surface adjacent the bottom cavity, the substrate having a length and width less than 5.0 millimeters;
b) a plurality of first contact pads located on the first surface;
c) a plurality of second contact pads located on the second surface;
d) a semiconductor die mounted to the second surface and electrically connected with the second contact pads;
e) a crystal mounted to the first surface, the crystal having a first end and a second end;
f) an electrode pad located at the first end of the crystal;
g) at least one thermosonically deposited metal bump attached between the electrode pad and the first contact pad, the metal bump providing an electrical connection between the crystal and the first contact pad, the metal bump mechanically supporting the crystal; and
h) a plurality of vias extending through the substrate for forming electrical connections between the first and second contact pads.

22. The oscillator according to claim 21 wherein a plurality of circuit lines are located in the wall and are electrically connected between the first and second contact pads.

23. The oscillator according to claim 21 wherein a sealant covers the semiconductor die in the bottom cavity.

24. The oscillator according to claim 21 wherein a seal ring is attached to the substrate around the top cavity.

25. The oscillator according to claim 24 wherein a cover is attached to the seal ring for hermetically sealing the top cavity.

26. An oscillator package having a length less than 7.0 millimeters and a width less than 5.0 millimeters, the package having an overall package area less than 35.0 square millimeters comprising:
a) a crystal receptacle having a first base and first side walls, the first side walls defining the crystal receptacle, the crystal receptacle having a receptacle area, the receptacle area taking up the majority of the overall package area;
b) an integrated circuit receptacle having a second base and second side walls, the second side walls defining the integrated circuit receptacle;
c) a planar crystal blank having a crystal area, the crystal blank mounted in the crystal receptacle, the crystal area taking up the majority of the receptacle area;
d) a first metal bump located between the base and the crystal, the metal bump affixing the crystal to the base;
e) an integrated circuit mounted in the integrated circuit receptacle; and
f) a second metal bump located between the second base and the integrated circuit, the second metal bump affixing the integrated circuit to the base.

27. The oscillator package according to claim 26, wherein the crystal has a first end and a second end, the first bump located at the first end.

28. The oscillator package according to claim 26, wherein the crystal and the integrated circuit are electrically interconnected through the first and second bases.

29. The oscillator package according to claim 26, wherein the integrated circuit receptacle has an integrated circuit receptacle area and the integrated circuit has an integrated circuit area, the integrated circuit area taking up the majority of the integrated circuit receptacle area.

30. The oscillator package according to claim 26, wherein the crystal receptacle is hermetically sealed by a cover mounted over the receptacle.

31. The oscillator package according to claim 26, wherein the metal bump is gold.

32. The oscillator package according to claim 26, wherein a plurality of contact pads are mounted to the first and the second bases, the metal bumps being mounted to the first and the second bases.
